(19) United States
(12) Patent Application Publication
(10) Pub. No.: US 2023/0350038 A1
(43) Pub. Date: Nov. 2, 2023

(54) OPTICAL SCANNING DEVICE AND ABNORMALITY DETECTION METHOD

(71) Applicant: FUJIFILM Corporation, Tokyo (JP)

(72) Inventors: Masaaki ABE, Kanagawa (JP); Takayuki NAONO, Kanagawa (JP); Yosuke NISHIURA, Kanagawa (JP)

(73) Assignee: FUJIFILM Corporation, Tokyo (JP)

(21) Appl. No.: 18/300,557

(22) Filed: Apr. 14, 2023

(30) Foreign Application Priority Data
Apr. 28, 2022 (JP) 2022-075199

(51) Int. Cl. G01S 7/497; G01S 7/481

(52) U.S. Cl. CPC G01S 7/497; G01S 7/4817

(57) ABSTRACT

An optical scanning device of the present disclosure includes: a micromirror device including a mirror that has a reflecting surface for reflecting light and is swingable around at least one axis, and an actuator that allows the mirror to swing; a control device configured to control an operation of the actuator; a light irradiation device configured to irradiate a back surface of the mirror on a side opposite to the reflecting surface with illumination light; a detection device to which reflected light of the illumination light that has been reflected by the mirror is incident and configured to output a position signal representing a position of the incidence light; and an abnormality detection device configured to detect an abnormal operation of the mirror based on a temporal fluctuation amount of the position signal.

### CROSS-REFERENCE TO RELATED APPLICATIONS

The present application claims priority under 35 U.S.C. § 119 to Japanese Patent Application No. 2022-075199 filed on Apr. 28, 2022. The above application is hereby expressly incorporated by reference, in its entirety, into the present application.

### BACKGROUND

### 1. Technical Field

The technology of the present disclosure relates to an optical scanning device and an abnormality detection method.

### 2. Description of the Related Art

A micromirror device (also referred to as a microscanner) is known as one of micro electro mechanical systems (MEMS) devices manufactured using a silicon (Si) nanofabrication technique. A mirror and an actuator that allows the mirror to swing are formed in the micromirror device. Since this micromirror device has a small size and low power consumption, the micromirror device is used in a laser scanner such as light detection and ranging (LiDAR) or head-up display (HUD).

In the laser scanner such as LiDAR or HUD, it is important to ensure user safety. For example, in a case in which an operation of the mirror is stopped in a state in which an output of laser light from a light source is on, it is dangerous because the laser light is continuously emitted to the same position. Therefore, it is required to detect an abnormal operation of the mirror during the operation. In order to detect the abnormal operation of the mirror, it is necessary to accurately detect a deflection angle of the mirror during the operation of the mirror.

JP2004-170499A discloses a method of detecting a deflection angle of a mirror by irradiating a back surface of a mirror with light, receiving the light reflected by the mirror with a light-receiving element, and calculating an output signal of the light-receiving element.

### SUMMARY

Although JP2004-170499A discloses the detection of the deflection angle of the mirror, it does not disclose detection of an abnormal operation of the mirror. In order to detect the abnormal operation of the mirror, a method of monitoring an amplitude of the mirror and determining that the abnormal operation has occurred in a case in which the amplitude falls outside a predetermined range is considered. However, since there is a need to acquire and evaluate a waveform for one swing period in order to detect the amplitude of the mirror, the abnormal operation of the mirror cannot be detected at high speed.

An object of the technology of the present disclosure is to provide an optical scanning device and an abnormality detection method with which an abnormal operation of a mirror can be detected at high speed during the operation.

In order to achieve the above object, an optical scanning device of the present disclosure comprises: a micromirror device including a mirror that has a reflecting surface for reflecting light and is swingable around at least one axis, and an actuator that allows the mirror to swing; a control device configured to control an operation of the actuator; a light irradiation device configured to irradiate a back surface of the mirror on a side opposite to the reflecting surface with illumination light; a detection device to which reflected light of the illumination light that has been reflected by the mirror is incident and configured to output a position signal representing a position of the incidence light; and an abnormality detection device configured to detect an abnormal operation of the mirror based on a temporal fluctuation amount of the position signal.

It is preferable that the detection device is a position sensitive detector capable of detecting a light quantity centroid position of the incidence light, and that the position signal represents the light quantity centroid position.

It is preferable that the control device causes the mirror to resonate with a fixed swing period by driving the actuator.

It is preferable that the abnormality detection device detects an amount by which the position signal fluctuates in a time interval smaller than 5% of the swing period, as the fluctuation amount.

It is preferable that the abnormality detection device detects an amount by which the position signal fluctuates in a time interval smaller than 5% and larger than 0.05% of the swing period, as the fluctuation amount.

It is preferable that the abnormality detection device includes a detection part configured to detect the fluctuation amount and a determination part configured to determine whether or not the fluctuation amount is equal to or greater than a threshold value.

It is preferable that the detection part is configured of a delay circuit that delays the position signal output from the detection device by a certain period of time, and a differential amplification circuit that amplifies and outputs a difference between the position signal output from the detection device and the position signal delayed by the delay circuit.

It is preferable that the determination part is a comparator.

It is preferable that the detection device is a position sensitive detector capable of simultaneously detecting the light quantity centroid position and an intensity of light of the incidence light, and that the abnormality detection device detects the abnormal operation based on an intensity signal representing the intensity of light output from the detection device in addition to the position signal.

It is preferable that the mirror is swingable around a first axis and a second axis that are orthogonal to each other, and that the detection device detects a two-dimensional position of the incidence light.

An abnormality detection method of the present disclosure is an abnormality detection method of an optical scanning device including a micromirror device including a mirror that has a reflecting surface for reflecting light and is swingable around at least one axis, and an actuator that allows the mirror to swing, and a control device configured to control an operation of the actuator, the method comprising: irradiating a back surface of the mirror on a side opposite to the reflecting surface with illumination light; and detecting an abnormal operation of the mirror based on a temporal fluctuation amount of a position of reflected light of the illumination light that has been reflected by the mirror.

According to the technology of the present disclosure, it is possible to provide an optical scanning device and an abnormality detection method with which an abnormal operation of a mirror can be detected at high speed during the operation.

### BRIEF DESCRIPTION OF THE DRAWINGS

Exemplary embodiments according to the technique of the present disclosure will be described in detail based on the following figures, wherein:

FIG. 1 is a schematic diagram of an optical scanning device,

FIG. 2 is a schematic diagram of a micromirror device,

FIG. 3 is a diagram showing a first deflection angle of a movable mirror,

FIG. 4 is a diagram showing a second deflection angle of the movable mirror,

FIG. 5 is a diagram showing an example of a driving signal applied to a first actuator and a second actuator,

FIG. 6 is a schematic diagram showing an example of a configuration of an angle detection device,

FIG. 7 is a block diagram showing an example of a configuration of an abnormality detection device,

FIG. 8 is a diagram schematically showing an example of an output signal, a delay signal, and a fluctuation amount in a case in which the movable mirror is normally operated,

FIG. 9 is a diagram schematically showing an example of an output signal, a delay signal, and a fluctuation amount in a case in which an abnormal operation occurs in the movable mirror,

FIG. 10 is a diagram showing an example of a position signal and an intensity signal output from a detection device,

FIG. 11 is a diagram showing an example of an optical method,

FIG. 12 is a diagram showing an evaluation result,

FIG. 13 is a diagram showing a waveform of a fluctuation amount in a case in which Δt/T=0.5%,

FIG. 14 is a diagram showing a waveform of a fluctuation amount in a case in which Δt/T=5%,

FIG. 15 is a diagram showing a waveform of a fluctuation amount in a case in which Δt/T=0.01%,

FIG. 16 is a diagram showing a determination example by a determination method in the related art based on a position signal,

FIG. 17 is a diagram showing a determination example by a determination method in the related art based on a position signal,

FIG. 18 is a block diagram showing a configuration of an abnormality detection device according to a modification example, and

FIG. 19 is a diagram showing an example of a determination method based on an intensity signal.

### DETAILED DESCRIPTION

An example of an embodiment relating to the technology of the present disclosure will be described with reference to the accompanying drawings.

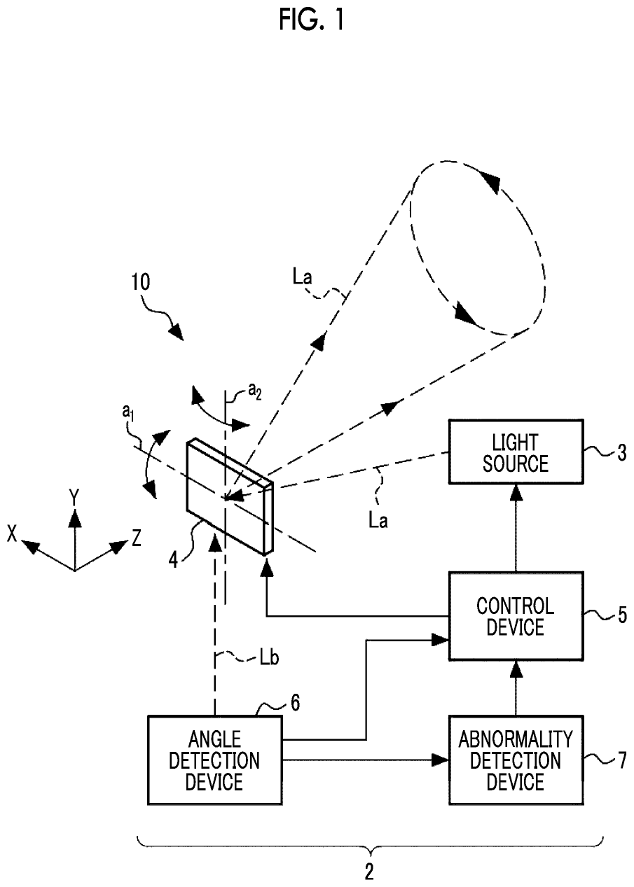

FIG. 1 schematically shows an optical scanning system 10 according to an embodiment. The optical scanning system 10 includes an optical scanning device 2 and a light source 3. The optical scanning device 2 includes a micromirror device (hereinafter, referred to as a micro mirror device (MMD)) 4, a control device 5, an angle detection device 6, and an abnormality detection device 7. The optical scanning system 10 is used in a laser scanner such as LiDAR or HUD.

The optical scanning device 2 performs optical scanning by reflecting laser light La incident from the light source 3 by the MMD 4 under a control of the control device 5. In a case in which the optical scanning system 10 is used in LiDAR, the optical scanning device 2 performs scanning with, for example, the laser light La in a helical shape. In the present embodiment, an optical scanning pattern is helical, but the optical scanning pattern is not limited to the helical shape and may be a Lissajous shape, a raster shape, or the like.

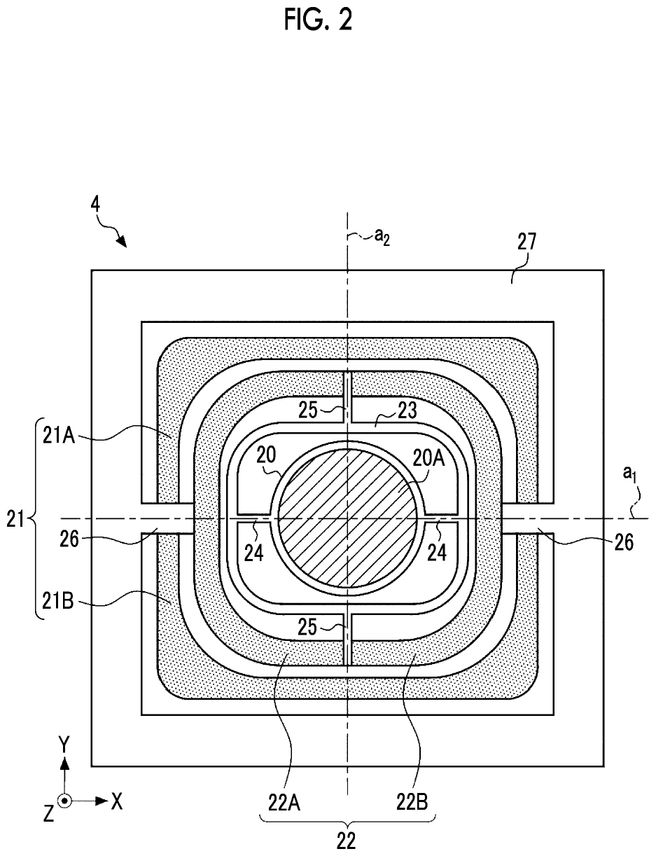

The MMD 4 is a piezoelectric biaxial drive type micromirror device capable of allowing a movable mirror 20 (see FIG. 2) to swing around a first axis a₁ and a second axis a₂ orthogonal to the first axis a₁. Hereinafter, a direction parallel to the first axis a₁ is referred to as an X direction, a direction parallel to the second axis a₂ is referred to as a Y direction, and a direction orthogonal to the first axis a₁ and the second axis a₂ is referred to as a Z direction.

The light source 3 is a laser device that emits the laser light La. The light source 3 emits the laser light La perpendicularly to a reflecting surface 20A (see FIG. 2) included in the movable mirror 20 in a state in which the movable mirror 20 of the MMD 4 is stationary. The laser light La is an example of “light” according to the technology of the present disclosure.

The control device 5 inputs a driving signal to the light source 3 and the MMD 4. The light source 3 generates the laser light L based on the input driving signal and emits the laser light La to the MMD 4. The MMD 4 allows the movable mirror 20 to swing around the first axis a₁ and the second axis a₂ based on the input driving signal.

The details will be described below, and the control device 5 causes the movable mirror 20 to resonate around the first axis a₁ and the second axis a₂. Thereby, a plane is scanned with the laser light La reflected by the movable mirror 20 such that a circle is drawn on the plane.

As will be described in detail below, the angle detection device 6 irradiates a back surface side of the movable mirror 20 (that is, a side opposite to a surface on which the laser light La is emitted) with illumination light Lb for angle detection, thereby detecting an angle of the movable mirror 20. The detection operation of the angle detection device 6 is controlled by the control device 5. For example, the control device 5 performs a feedback control of correcting the driving signal based on a signal output from the angle detection device 6.

Details will be described later, but the abnormality detection device 7 detects an abnormal operation of the movable mirror 20 during operation based on a temporal fluctuation amount of a signal output from the angle detection device 6.

Next, an example of a configuration of the MMD 4 will be described with reference to FIG. 2. FIG. 2 is a schematic diagram of the MMD 4.

The MMD 4 has a movable mirror 20, a first actuator 21, a second actuator 22, a support frame 23, a first support portion 24, a second support portion 25, a connecting portion 26, and a fixed portion 27. The MMD 4 is formed, for example, by performing an etching treatment on a silicon on insulator (SOI) substrate. The movable mirror 20 is an example of a “mirror” according to the technology of the present disclosure.

The movable mirror 20 has a reflecting surface 20A for reflecting incidence light. The reflecting surface 20A is provided on one surface of the movable mirror 20, and is formed of a metal thin film such as gold (Au) and aluminum (Al). The reflecting surface 20A is, for example, circular.

The support frame 23 is disposed to surround the movable mirror 20. The second actuator 22 is disposed to surround the movable mirror 20 and the support frame 23. The first actuator 21 is disposed to surround the movable mirror 20, the support frame 23, and the second actuator 22.

The first support portion 24 connects the movable mirror 20 and the support frame 23 on the first axis a₁, and swingably supports the movable mirror 20 around the first axis a₁. The first axis a₁ is located in a plane including the reflecting surface 20A in a case in which the movable mirror 20 is stationary. For example, the first support portion 24 is a torsion bar stretched along the first axis a₁.

The second support portion 25 connects the support frame 23 and the second actuator 22 on the second axis a₂, and swingably supports the movable mirror 20 and the support frame 23 around the second axis a₂. The second axis a₂ is orthogonal to the first axis a₁ in the plane including the reflecting surface 20A in a case in which the movable mirror 20 is stationary.

The connecting portion 26 connects the first actuator 21 and the second actuator 22 on the first axis a₁. In addition, the connecting portion 26 connects the first actuator 21 and the fixed portion 27 on the first axis a₁.

The fixed portion 27 has a rectangular outer shape and surrounds the first actuator 21. Lengths of the fixed portion 27 in the X direction and the Y direction are, for example, about 1 mm to 10 mm, respectively. A thickness of the fixed portion 27 in the Z direction is, for example, about 5 μm to 0.2 mm.

The first actuator 21 and the second actuator 22 are piezoelectric actuators each comprising a piezoelectric element. The first actuator 21 applies rotational torque around the first axis a₁ to the movable mirror 20. The second actuator 22 applies rotational torque around the second axis a₂ to the movable mirror 20. Thereby, the movable mirror 20 swings around the first axis a₁ and around the second axis a₂.

The first actuator 21 is an annular thin plate member that surrounds the movable mirror 20, the support frame 23, and the second actuator 22 in the XY plane. The first actuator 21 is composed of a pair of a first movable portion 21A and a second movable portion 21B. Each of the first movable portion 21A and the second movable portion 21B is substantially semi-annular. The first movable portion 21A and the second movable portion 21B have a shape that is line-symmetrical with respect to the first axis a₁, and are connected on the first axis a₁.

The support frame 23 is an annular thin plate member that surrounds the movable mirror 20 in the XY plane.

The second actuator 22 is an annular thin plate member that surrounds the movable mirror 20 and the support frame 23 in the XY plane. The second actuator 22 is composed of a pair of a first movable portion 22A and a second movable portion 22B. Each of the first movable portion 22A and the second movable portion 22B is semi-annular. The first movable portion 22A and the second movable portion 22B have a shape that is line-symmetrical with respect to the second axis a₂, and are connected on the second axis a₂.

In the first actuator 21, the first movable portion 21A and the second movable portion 21B are each provided with a piezoelectric element. In addition, in the second actuator 22, the first movable portion 22A and the second movable portion 22B are each provided with a piezoelectric element.

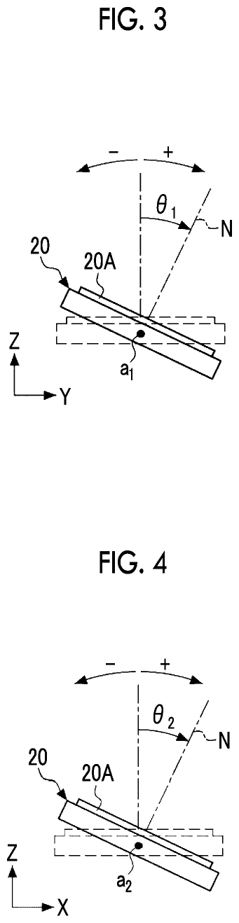

FIG. 3 and FIG. 4 show a deflection angle in a case in which the movable mirror 20 swings. FIG. 3 shows a deflection angle (hereinafter, referred to as a first deflection angle) θ₁ of the movable mirror 20 around the first axis a₁. FIG. 4 shows a deflection angle (hereinafter, referred to as a second deflection angle) θ₂ of the movable mirror 20 around the second axis a₂.

As shown in FIG. 3, an angle at which a normal line N of the reflecting surface 20A of the movable mirror 20 is inclined in the YZ plane is called a first deflection angle θ₁. In a case in which the normal line N of the reflecting surface 20A is inclined in the +Y direction, the first deflection angle θ₁ takes a positive value, and in a case in which it is inclined in the −Y direction, the first deflection angle θ₁ takes a negative value.

The first deflection angle θ₁ is controlled by the driving signal (hereinafter, referred to as a first driving signal) applied to the first actuator 21 by the control device 5. The first driving signal is, for example, a sinusoidal AC voltage. The first driving signal includes a driving voltage waveform V_{1A} (t) applied to the first movable portion 21A and a driving voltage waveform V_{1B} (t) applied to the second movable portion 21B. The driving voltage waveform V_{1A} (t) and the driving voltage waveform V_{1B} (t) are in an anti-phase with each other (that is, a phase difference is 180°.

As shown in FIG. 4, an angle at which a normal line N of the reflecting surface 20A of the movable mirror 20 is inclined in the XZ plane is called a second deflection angle θ₂. In a case in which the normal line N of the reflecting surface 20A is inclined in the +X direction, the second deflection angle θ₂ takes a positive value, and in a case in which it is inclined in the −X direction, the second deflection angle θ₂ takes a negative value.

The second deflection angle θ₂ is controlled by the driving signal (hereinafter, referred to as a second driving signal) applied to the second actuator 22 by the control device 5. The second driving signal is, for example, a sinusoidal AC voltage. The second driving signal includes a driving voltage waveform V_{2A} (t) applied to the first movable portion 22A and a driving voltage waveform V_{2B} (t) applied to the second movable portion 22B. The driving voltage waveform V_{2A} (t) and the driving voltage waveform V_{2B} (t) are in an anti-phase with each other (that is, the phase difference is 180°.

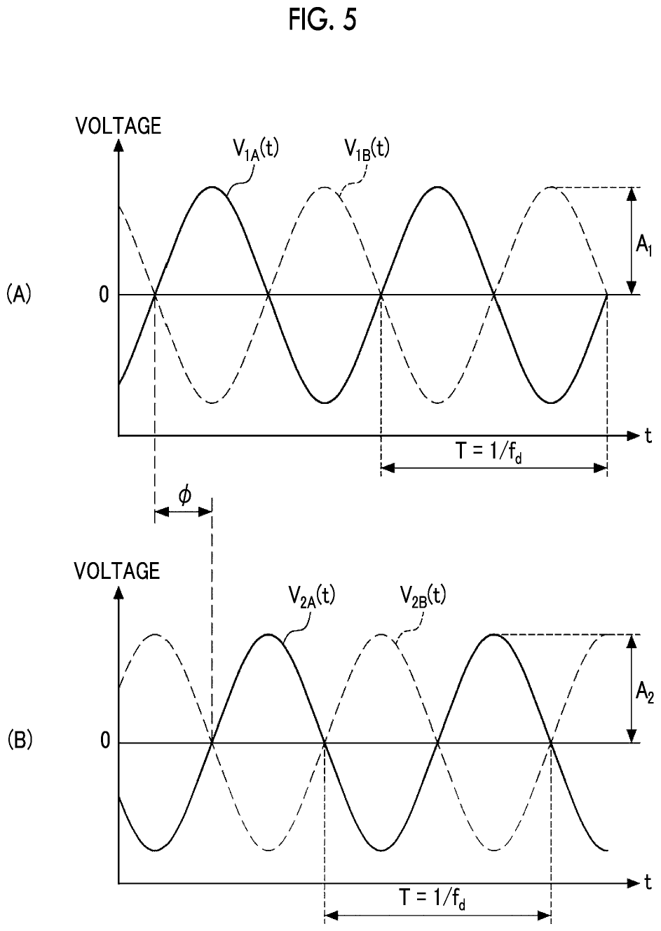

FIG. 5 shows an example of a driving signal applied to the first actuator 21 and the second actuator 22. (A) of FIG. 5 shows the driving voltage waveforms V_{1A} (t) and V_{1B} (t) included in the first driving signal. (B) of FIG. 5 shows the driving voltage waveforms V_{2A} (t) and V_{2B} (t) included in the second driving signal.

The driving voltage waveforms V_{1A} (t) and V_{1B} (t) are represented by Equations (1A) and (1B), respectively.

V_{1A}(t)=A₁ sin(2πf_{d}t) (1A)

V_{1B}(t)=A₁ sin(2πf_{d}t+π) (1B)

Here, t is a time. f_{d} is a driving frequency. A₁ is an amplitude. A phase difference between the driving voltage waveform V_{1A} (t) and the driving voltage waveform V_{1B} (t) is π (that is, 180°).

The driving voltage waveforms V_{2A} (t) and V_{2B} (t) are represented by Equations (2A) and (2B), respectively.

V_{2A}(t)=A₂ sin(2πf_{d}t+ϕ) (2A)

V_{2B}(t)=A₂ sin(2πf_{d}t+π+φ) (2B)

Here, A₂ is an amplitude. A phase difference between the driving voltage waveform V_{2A} (t) and the driving voltage waveform V_{2B} is π (that is, 180°). φ is a phase difference between the driving voltage waveform V_{1A} (t) and the driving voltage waveform V_{2A} (t). In the present embodiment, φ=90° is set in order to cause the movable mirror 20 to perform precession to form the optical scanning pattern in a helical shape. Note that the amplitudes A₁ and A₂ may be changed in accordance with the time t.

In the present embodiment, the driving frequency f_{d} is set as a resonance frequency of the movable mirror 20. Thereby, the movable mirror 20 resonates with a fixed swing period T. The swing period T is represented by T=1/f_{d}.

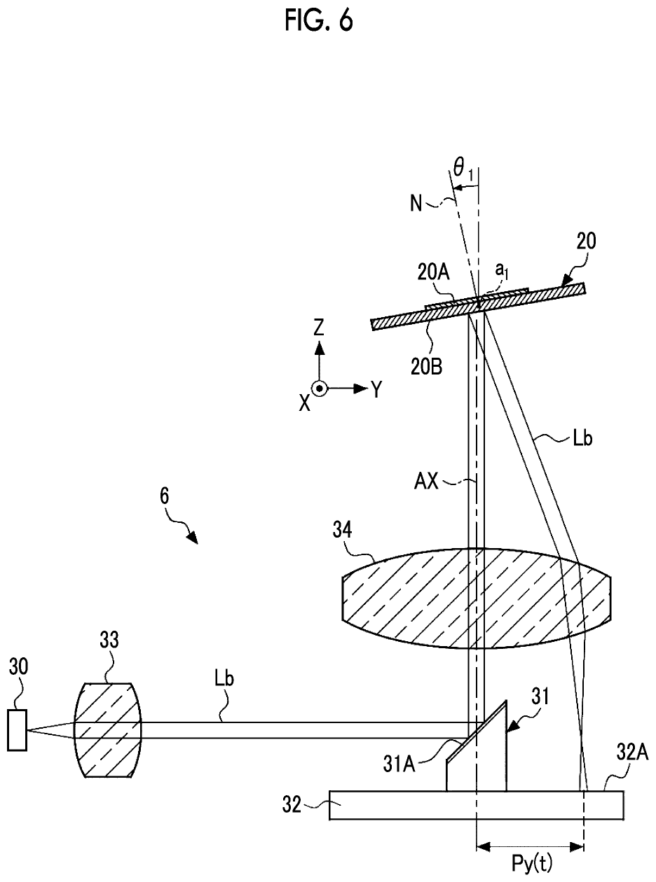

FIG. 6 shows an example of a configuration of the angle detection device 6. As shown in FIG. 6, the angle detection device 6 comprises a light irradiation device 30, a light deflection member 31, a detection device 32, a collimating lens 33, and a condenser lens 34. The light irradiation device 30 emits illumination light Lb for angle detection. For example, the light irradiation device 30 is a laser diode that emits laser light having a wavelength of about 980 nm as the illumination light Lb.

The light deflection member 31 has a cut surface formed by cutting a base material of a cylinder obliquely with respect to a rotational symmetry axis of the cylinder, and a reflecting surface 31A is formed on the cut surface. The light deflection member 31 is disposed such that the illumination light Lb emitted from the light irradiation device 30 is incident on the reflecting surface 31A at an incidence angle of about 45°.

The collimating lens 33 is disposed between the light irradiation device 30 and the light deflection member 31. The illumination light Lb emitted from the light irradiation device 30 is incident on the reflecting surface 31A via the collimating lens 33. A traveling direction of the illumination light Lb emitted from the light irradiation device 30 is, for example, the Y direction. The illumination light Lb incident on the reflecting surface 31A travels in the Z direction by being deflected by an angle of 90°, and is incident on a back surface 20B of the movable mirror 20. The back surface 20B is a surface opposite to the surface of the movable mirror 20 on which the reflecting surface 20A is provided. Although not shown, a beam structure (also referred to as a rib) is provided on the back surface 20B in order to enhance the strength of the movable mirror 20.

The condenser lens 34 is disposed between the light deflection member 31 and the movable mirror 20. The condenser lens 34 is, for example, a biconvex lens, and is disposed such that the illumination light Lb deflected by the light deflection member 31 travels along an optical axis AX thereof. The illumination light Lb passes through the center of the condenser lens 34 and is incident on the back surface 20B of the movable mirror 20.

The illumination light Lb incident on the back surface 20B of the movable mirror 20 is reflected at a reflection angle corresponding to the deflection angle (first deflection angle θ₁ and second deflection angle θ₂) of the movable mirror 20. The illumination light Lb that has been reflected by the back surface 20B of the movable mirror 20 is incident on a light-receiving surface 32A of the detection device 32 via the condenser lens 34. The light deflection member 31 is disposed at the center of the light-receiving surface 32A.

The detection device 32 is a position sensitive detector capable of detecting a light quantity centroid position of the incidence light, and outputs a position signal representing the light quantity centroid position. In the present embodiment, as the detection device 32, a two-dimensional position sensitive detector (PSD) that detects a two-dimensional position of the incidence light is used. The detection device 32 detects the light quantity centroid position in the X direction and the light quantity centroid position in the Y direction, of the incidence light on the light-receiving surface 32A. The detection device 32 outputs a position signal Px (t) representing the light quantity centroid position in the X direction and a position signal Py (t) representing the light quantity centroid position in the Y direction. As shown in FIG. 6, the position signal Py (t) changes in accordance with the first deflection angle θ₁. Although not shown, the position signal Px (t) changes in accordance with the second deflection angle θ₂.

The detection device 32 of the present embodiment makes it possible to simultaneously detect the light quantity centroid position and an intensity of light of the incidence light, and outputs intensity signals Ix (t) and Iy (t) representing the intensity of the incidence light in addition to the position signals Px (t) and Py (t). The intensity signal Ix (t) represents the intensity of light in the X direction. The intensity signal Iy (t) represents the intensity of light in the Y direction.

The control device 5 performs a feedback control of correcting the first driving signal and the second driving signal based on the position signals Px (t) and Py (t) output from the angle detection device 6.

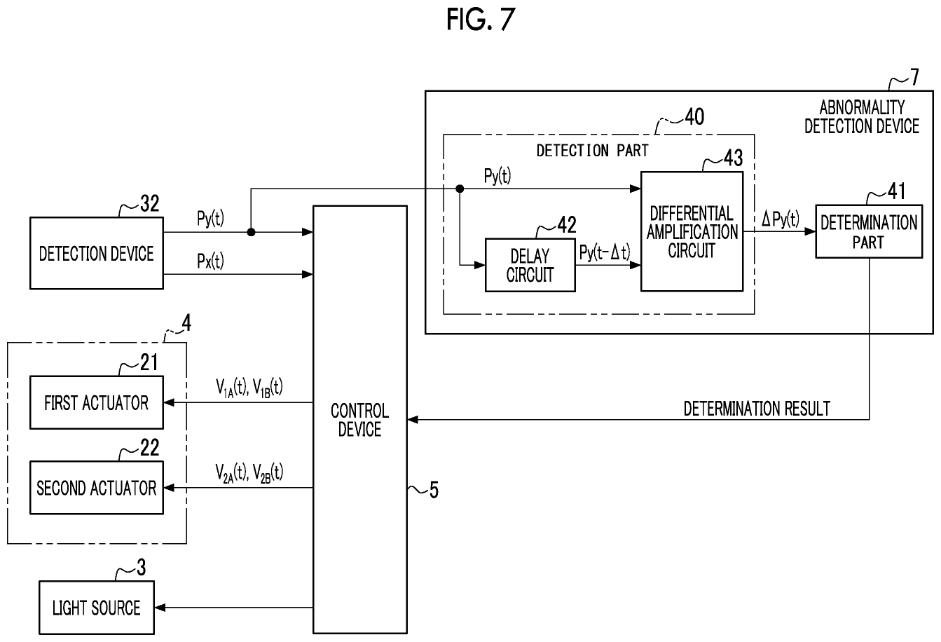

FIG. 7 shows an example of a configuration of the abnormality detection device 7. The abnormality detection device 7 includes a detection part 40 and a determination part 41. The detection part 40 is composed of a delay circuit 42 and a differential amplification circuit 43. In the present embodiment, the abnormality detection device 7 performs abnormality detection using the position signal Py (t) out of the position signals Px (t) and Py (t) output from the detection device 32.

The position signal Py (t) is input to the detection part 40. Specifically, the position signal Py (t) is input to the delay circuit 42 and the differential amplification circuit 43. The delay circuit 42 delays the input position signal Py (t) by a certain period of time Δt and outputs the signal. Hereinafter, the signal output from the delay circuit 42 is referred to as a delay signal Py (t−Δt). Hereinafter, the time Δt is referred to as a delay time Δt. The delay time Δt is shorter than the swing period T.

The delay signal Py (t−Δt) output from the delay circuit 42 is input to the differential amplification circuit 43. The differential amplification circuit 43 amplifies and outputs a difference between the position signal Py (t) and the delay signal Py (t−Δt). That is, the delay circuit 42 adjusts a phase of the position signal Py (t) to obtain the delay signal Py (t−Δt). Hereinafter, the output signal output from the differential amplification circuit 43 is referred to as a fluctuation amount ΔPy (t). The fluctuation amount ΔPy (t) represents a temporal fluctuation amount of the position signal Py (t). In other words, the fluctuation amount ΔPy (t) represents an amount by which the position signal Py (t) fluctuates in a time interval smaller than the swing period T.

The fluctuation amount ΔPy (t) output from the differential amplification circuit 43 is input to the determination part 41. The determination part 41 is composed of a comparator. The determination part 41 determines whether or not the fluctuation amount ΔPy (t) is equal to or greater than a threshold value Vth, and outputs a determination result to the control device 5. Here, the fact that the fluctuation amount ΔPy (t) is equal to or greater than the threshold value Vth means that an absolute value of the fluctuation amount ΔPy (t) is equal to or greater than the threshold value Vth, in other words, ΔPy (t)≥Vth, or ΔPy (t)≤−Vth.

The control device 5 stops the operations of the light source 3 and the MMD 4 according to the determination result output from the determination part 41. Specifically, the control device 5 stops the operations of the light source 3 and the MMD 4 in a case in which the determination part 41 determines that the fluctuation amount ΔPy (t) is equal to or greater than the threshold value Vth.

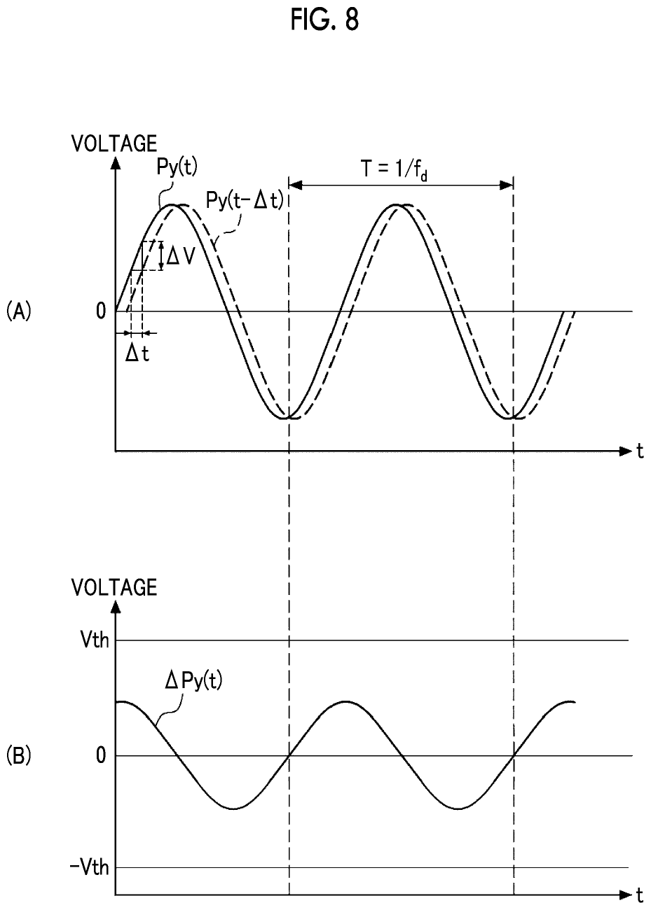

FIG. 8 schematically shows an example of the position signal Py (t), the delay signal Py (t−Δt), and the fluctuation amount ΔPy (t) in a case in which the movable mirror 20 is normally operated. (A) of FIG. 8 shows an example of the position signal Py (t) and the delay signal Py (t−Δt). (B) of FIG. 8 shows an example of the fluctuation amount ΔPy (t).

In a case in which the movable mirror 20 resonates with a fixed swing period T, the position signal Py (t) ideally becomes a substantially sinusoidal wave, as shown in (A) of FIG. 8. In (A) of FIG. 8, the position signal Py (t) is shown by a solid line, and the delay signal Py (t−Δt) is shown by a broken line. The fluctuation amount ΔPy (t) shown in (B) of FIG. 8 corresponds to a fluctuation voltage ΔV of the position signal Py (t) with respect to the delay time Δt. The fluctuation amount ΔPy (t) ideally becomes a substantially sinusoidal wave.

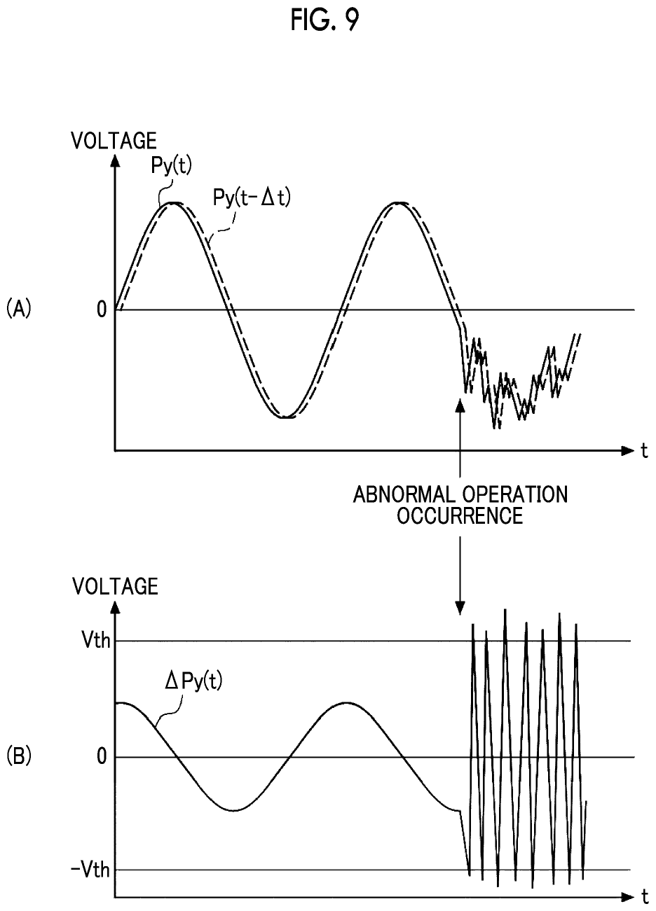

FIG. 9 schematically shows an example of the position signal Py (t), the delay signal Py (t−Δt), and the fluctuation amount ΔPy (t) in a case in which an abnormal operation occurs in the movable mirror 20. (A) of FIG. 9 shows an example of the position signal Py (t) and the delay signal Py (t−Δt). (B) of FIG. 9 shows an example of the fluctuation amount ΔPy (t).

As shown in FIG. 9, in a case in which an abnormal operation occurs in the movable mirror 20, the fluctuation amount ΔPy (t) greatly changes to be equal to or greater than the threshold value Vth, and the determination part 41 determines that the operation of the movable mirror 20 is abnormal.

Even in a case in which the operation of the movable mirror 20 is normal, noise may be generated in a waveform of the position signal Py (t) because of stray light or the like being included in the reflected light from the back surface 20B of the movable mirror 20. The stray light is caused, for example, by the illumination light Lb being reflected by a beam structure or the like provided on the back surface 20B. In order to accurately detect the abnormal operation of the movable mirror 20 regardless of the influence of noise or the like, it is necessary to set the delay time Δt within an appropriate range. Specifically, it is preferable to set a ratio (Δt/T) of the delay time Δt to the swing period T within an appropriate range.

For example, it is preferable to define an upper limit value to satisfy Δt/T<5%. In this case, the detection part 40 detects an amount by which the position signal Py (t) fluctuates in a time interval smaller than 5% of the swing period T, as the fluctuation amount ΔPy (t). In addition, it is more preferable to define an upper limit value and a lower limit value to satisfy 0.05%<Δt/T<5%. In this case, the detection part 40 detects an amount by which the position signal Py (t) fluctuates in a time interval smaller than 5% and greater than 0.05% of the swing period T, as the fluctuation amount ΔPy (t).

### Verification of Effect by Experiment

By using the abnormality detection device 7 configured as described above, it is possible to detect the abnormal operation of the movable mirror 20 at high speed during the operation. In order to verify this effect, the present applicant manufactured a plurality of the MMD 4s and conducted an experiment.

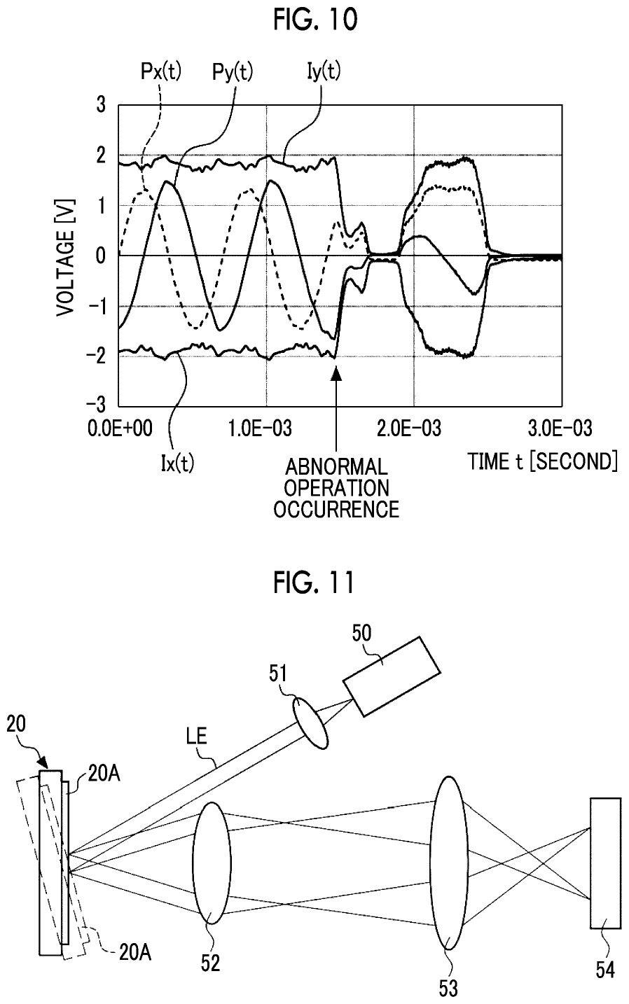

With the manufactured MMD 4 having a driving frequency f_{d} of about 1420 Hz and the movable mirror 20 performing precession, the signals output from the detection device 32 were input to the abnormality detection device 7 to evaluate an accuracy of abnormality detection. The swing period T is about 704 μs. FIG. 10 shows an example of the position signals Px (t) and Py (t) and the intensity signals Ix (t) and Iy (t) output from the detection device 32. In this experiment, the position signal Py (t) was input to the abnormality detection device 7. The abnormality detection device 7 evaluated an accuracy of abnormality detection for a plurality of ratios Δt/T by changing the delay time Δt.

In addition, since an abnormal operation is less likely to occur in a normal environment, an abnormal operation was caused to generate by operating the MMD 4 in a load environment. The load includes driving the MMD 4 in a high-temperature and high-humidity environment, applying an impact to the MMD 4 from an outside, and driving the MMD 4 with a high driving voltage.

A determination result of the abnormal operation based on a measured value obtained by directly measuring the operation of the movable mirror 20 by an optical method was used as an evaluation standard. FIG. 11 shows an example of the optical method. As shown in FIG. 11, evaluation laser light LE is emitted from an evaluation light source 50 to the reflecting surface 20A of the movable mirror 20 via a collimating lens 51, and reflected light from the reflecting surface 20A is formed into an image on a position sensitive detector (PSD) 54 via lenses 52 and 53. An image forming position obtained by the position sensitive detector is converted into a deflection angle of the movable mirror 20. In order to improve a conversion accuracy of the deflection angle, it is preferable that a reference mirror having a known angle is installed instead of the MMD 4 and that calibration for calibrating an angle and position information is executed.

The deflection angle (the first deflection angle θ₁ and the second deflection angle θ₂) of the movable mirror 20 was measured by the optical method described above, and a composite angle obtained by combining the first deflection angle θ₁ and the second deflection angle θ₂ was calculated. In a case in which the movable mirror 20 performs precession, the composite angle is constant. In a case in which the composite angle exceeds a range of ±10% from a steady-state value, it is determined that an abnormal operation has occurred, and a time at which the determination is made was used as a reference time.

The accuracy of abnormality detection by the abnormality detection device 7 was evaluated for a plurality of evaluation items. The evaluation items used in this experiment are “detection time”, “detection omission”, and “erroneous detection”. The detection time is an evaluation item relating to a time at which an abnormal operation was detected (abnormality detection time). The detection omission is an evaluation item relating to whether or not an abnormal operation could be detected. The erroneous detection is an evaluation item relating to whether or not an abnormal operation was erroneously detected during a period from a start of the operation to the occurrence of the abnormal operation.

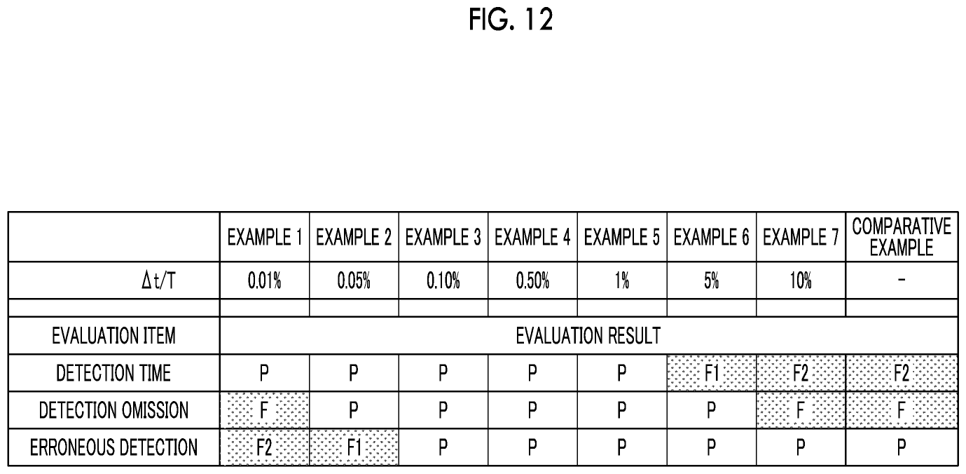

FIG. 12 shows an evaluation result. Examples 1 to 7 are experimental examples of abnormality detection using the abnormality detection device 7 of the present embodiment, in which the ratios Δt/T are different from each other because of different set values of the delay time Δt. A comparative example is an experimental example of abnormality detection using the determination method in the related art based on the position signal Py (t) without using the abnormality detection device 7 of the present embodiment.

In the evaluation result of the detection time, P indicates that, as a result of conducting the experiment using 100 samples, the latest abnormality detection time (worst detection time) was less than 350 μs from the above-described reference time. F1 indicates that the worst detection time was less than 700 μs from the reference time. F2 indicates that the worst detection time was equal to or more than 700 μs from the reference time.

In the evaluation result of the detection omission, P indicates that, as a result of conducting the experiment using 100 samples, the abnormal operation could be detected for all the samples, that is, there was no detection omission. F indicates that the abnormal operation could not be detected for at least one sample, that is, there was a detection omission.

In the evaluation result of the erroneous detection, P indicates that, as a result of conducting the experiment using 100 samples, a value (erroneous detection rate) obtained by dividing the number of erroneously detected samples by the total number of the samples was less than 10%. F1 indicates that an erroneous detection rate was less than 50%. F2 indicates that an erroneous detection rate was equal to or more than 50%.

According to the evaluation result of the detection time, it can be seen that the worst detection time is less than 350 μs from the reference time in a case in which Δt/T<5%. That is, it is preferable that Δt/T<5% in order to detect the abnormal operation of the movable mirror 20 at high speed during the operation.

According to the evaluation result of the detection omission, it can be seen that the detection omission does not occur in a case in which 0.01<Δt/T<10%. That is, from the viewpoint of detection omission, it is preferable that the lower limit value of Δt/T is 0.01%.

According to the evaluation result of the erroneous detection, it can be seen that the erroneous detection does not occur in a case in which 0.05%<Δt/T. The erroneous detection is mainly caused by noise due to stray light. That is, from the viewpoint of noise immunity, it is preferable that the lower limit value of Δt/T is 0.05%.

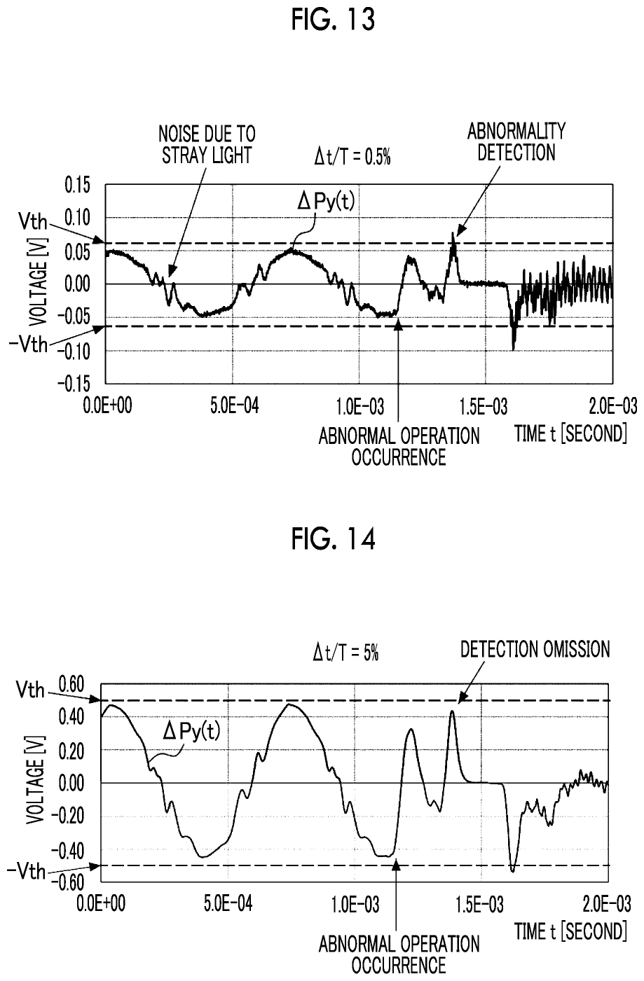

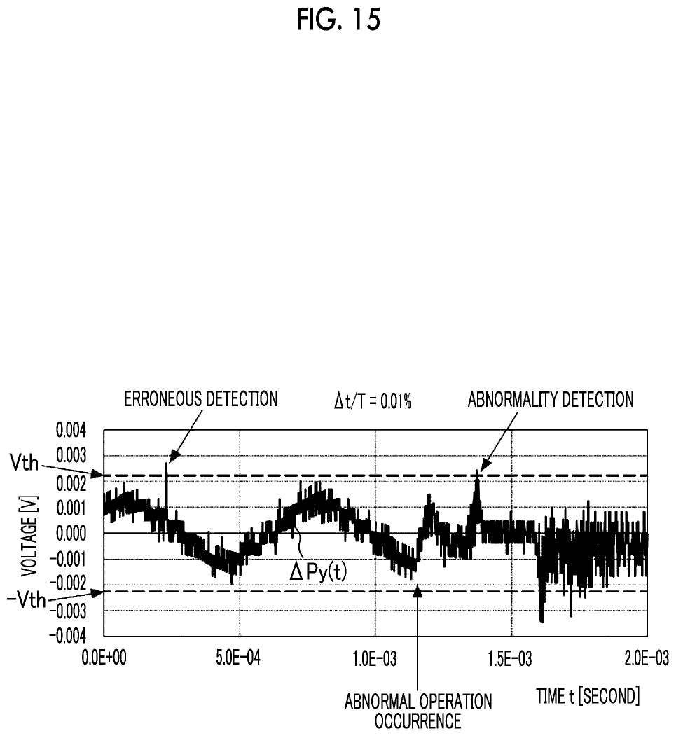

FIGS. 13 to 15 show a waveform of the fluctuation amount ΔPy (t). FIG. 13 shows a waveform of the fluctuation amount ΔPy (t) in a case in which Δt/T=0.5%. FIG. 14 shows a waveform of the fluctuation amount ΔPy (t) in a case in which Δt/T=5%. FIG. 15 shows a waveform of the fluctuation amount ΔPy (t) in a case in which Δt/T=0.01%.

FIG. 13 shows an example of a waveform that enables the abnormality detection at high speed and with high accuracy in a case in which 0.05%<Δt/T<10%. In the waveform shown in FIG. 13, since the amplitude during the abnormal operation is larger than the amplitude during the normal operation, the abnormal operation can be detected at high speed and with high accuracy. In addition, FIG. 13 shows that even in a case in which noise due to stray light is mixed in the waveform, a relationship between the amplitudes is maintained, and the abnormal operation can be stably detected.

FIG. 14 shows an example of a waveform in which the detection omission occurs in a case in which Δt/T>5%. In the waveform shown in FIG. 14, since the amplitude during the abnormal operation is smaller than the amplitude during the normal operation, the abnormal operation cannot be detected, and the detection omission occurs.

FIG. 15 shows an example of a waveform in which the erroneous detection occurs in a case in which Δt/T<0.05%. Since the waveform shown in FIG. 15 has small amplitudes during the normal operation and the abnormal operation, it is susceptible to noise due to stray light, and the erroneous detection is likely to occur.

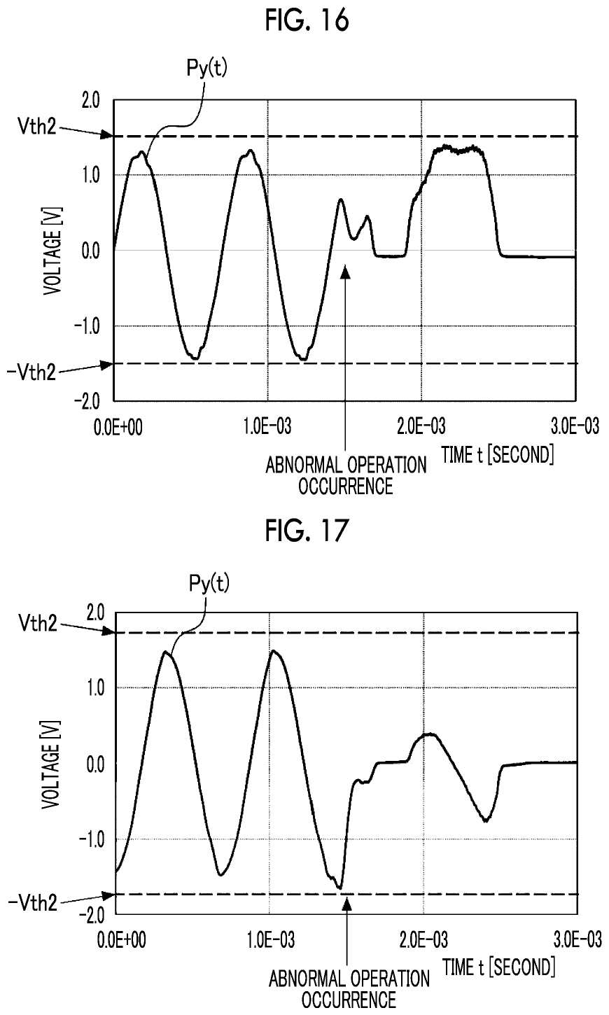

FIG. 16 and FIG. 17 show a determination example by the determination method in the related art based on the position signal Py (t). In the determination method in the related art, the abnormality detection is performed by comparing the position signal Py (t) with a threshold value Vth2. In each of the waveforms shown in FIGS. 16 and 17, the amplitude decreases after the occurrence of the abnormal operation, and the abnormal operation cannot be detected, resulting in detection omission. In a case in which the amplitude increases after the occurrence of the abnormal operation, the abnormal operation is detected even by the determination method in the related art, but it takes a time for the position signal Py (t) to exceed the threshold value Vth2 after the occurrence of the abnormal operation. Therefore, the abnormality detection cannot be performed at high speed.

### Various Modification Examples

In the above-described embodiment, although the abnormality detection device 7 performs the abnormality detection based on the position signal Py (t), the abnormality detection device 7 may perform the abnormality detection based on the position signal Px (t). In addition, the abnormality detection device 7 may perform the abnormality detection based on each of the position signals Py (t) and Px (t). In this case, for example, the abnormality detection device 7 determines that the abnormal operation has occurred in a case in which the temporal fluctuation amount of any one of the position signals Py (t) and Px (t) is equal to or greater than the threshold value.

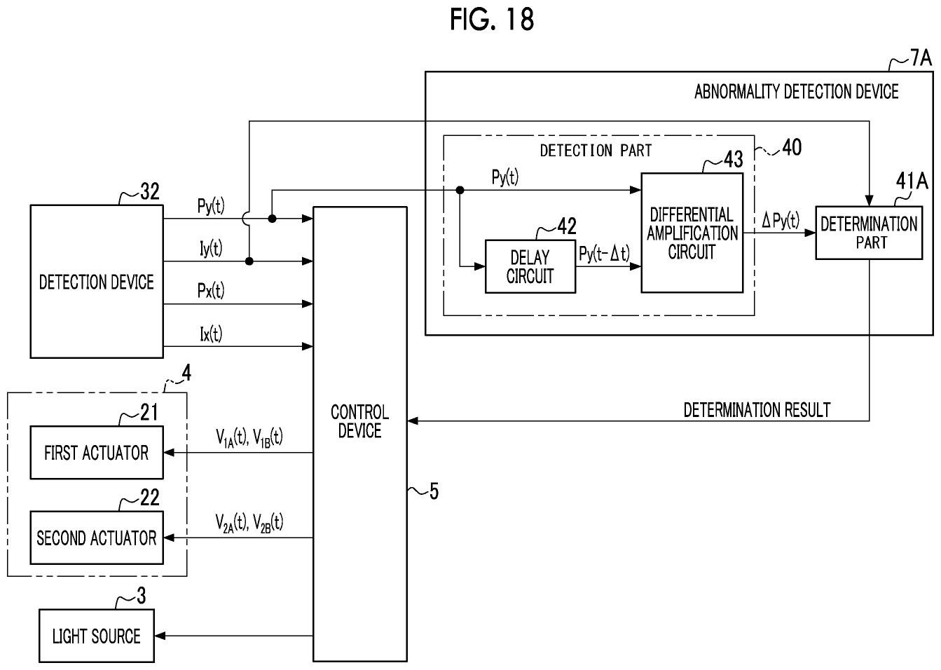

In addition, the abnormality detection device 7 may perform the abnormality detection based on the intensity signal in addition to the position signal. FIG. 18 shows a configuration of an abnormality detection device 7A according to a modification example. The abnormality detection device 7A performs the abnormality detection based on the intensity signal Iy (t) in addition to the position signal Py (t) output from the detection device 32. The abnormality detection device 7A includes a detection part 40 and a determination part 41A. The determination part 41A performs the above-described determination based on the fluctuation amount ΔPy (t) of the position signal Py (t), and also performs the determination based on the intensity signal Iy (t).

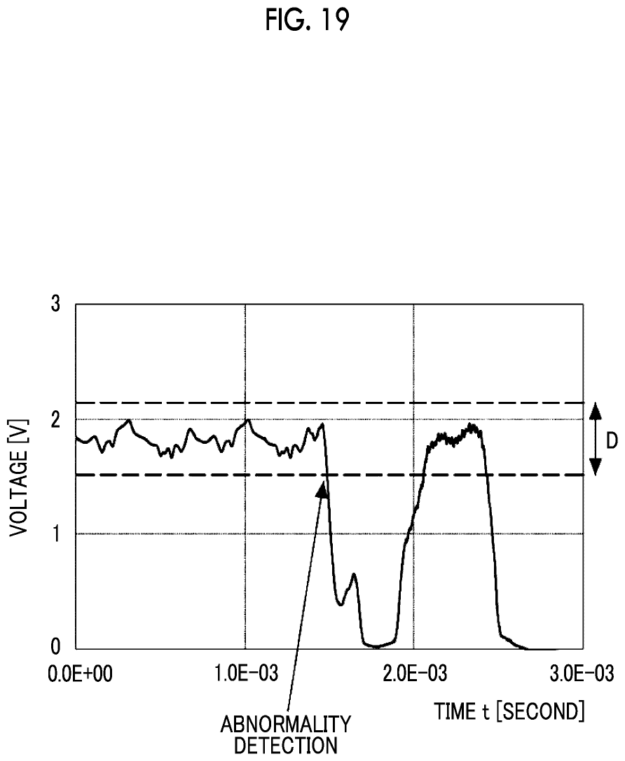

FIG. 19 shows an example of a determination method based on the intensity signal Iy (t). Although the intensity signal Iy (t) fluctuates within a certain range D in a case in which the movable mirror 20 performs a normal operation, the intensity signal Iy (t) falls outside the certain range D in a case in which an abnormal operation occurs in the movable mirror 20. Therefore, the determination part 41A monitors the intensity signal Iy (t), and determines that the abnormal operation has occurred in a case in which the intensity signal Iy (t) falls outside the certain range D. In this way, by performing the abnormality detection based on the intensity signal in addition to the position signal, the accuracy of the abnormality detection is further improved.

The abnormality detection may be performed based on all of the position signals Px (t) and Py (t) and the intensity signals Ix (t) and Iy (t).

In the above-described embodiment, although the detection part 40 is composed of the delay circuit 42 and the differential amplification circuit 43, the detection part 40 may be composed of a differential circuit. In addition, the detection part 40 may be composed of a high-pass filter. In this case, a cutoff frequency of the high-pass filter need only be set in accordance with the upper limit value of Δt/T. In addition, the detection part 40 may be composed of a band-pass filter. In this case, cutoff frequencies on a high frequency side and a low frequency side of the band-pass filter need only be set in accordance with the lower limit value and the upper limit value of Δt/T.

In addition, in the above-described embodiment, although the abnormality detection device 7 is composed of an analog circuit, a part or entirety of the abnormality detection device 7 may be composed of a digital circuit. For example, a signal obtained by digitizing the position signal Py (t) with an analog to digital converter (ADC) may be processed by software (program). In this case, a general-purpose processor can be used as the abnormality detection device 7. The general-purpose processor includes a central processing unit (CPU), a programmable logic device (PLD), a dedicated electric circuit, or the like. The processor performs detection processing and determination processing.

In addition, in the above-described embodiment, although a micromirror device having a mirror swingable around two axes is used, the micromirror device may have a mirror swingable around one axis. That is, the micromirror device need only include a mirror swingable around at least one axis, and an actuator that allows the mirror to swing. The detection device is not limited to a device that detects a two-dimensional position of the incidence light, and may be a device that detects a one-dimensional position of the incidence light.

All documents, patent applications, and technical standards mentioned in this specification are incorporated herein by reference to the same extent as in a case where each document, each patent application, and each technical standard are specifically and individually described by being incorporated by reference.

What is claimed is:

1. An optical scanning device comprising:
a micromirror device including a mirror that has a reflecting surface for reflecting light and is swingable around at least one axis, and an actuator that allows the mirror to swing;
a control device configured to control an operation of the actuator;
a light irradiation device configured to irradiate a back surface of the mirror on a side opposite to the reflecting surface with illumination light;
a detection device to which reflected light of the illumination light that has been reflected by the mirror is incident and configured to output a position signal representing a position of the incidence light; and
an abnormality detection device configured to detect an abnormal operation of the mirror based on a temporal fluctuation amount of the position signal.

2. The optical scanning device according to claim 1,
wherein the detection device is a position sensitive detector capable of detecting a light quantity centroid position of the incidence light, and
the position signal represents the light quantity centroid position.

3. The optical scanning device according to claim 1,
wherein the control device causes the mirror to resonate with a fixed swing period by driving the actuator.

4. The optical scanning device according to claim 3,
wherein the abnormality detection device detects an amount by which the position signal fluctuates in a time interval smaller than 5% of the swing period, as the fluctuation amount.

5. The optical scanning device according to claim 3,
wherein the abnormality detection device detects an amount by which the position signal fluctuates in a time interval smaller than 5% and larger than 0.05% of the swing period, as the fluctuation amount.

6. The optical scanning device according to claim 3,
wherein the abnormality detection device includes a detection part configured to detect the fluctuation amount and a determination part configured to determine whether or not the fluctuation amount is equal to or greater than a threshold value.

7. The optical scanning device according to claim 6,
wherein the detection part is configured of
a delay circuit that delays the position signal output from the detection device by a certain period of time, and
a differential amplification circuit that amplifies and outputs a difference between the position signal output from the detection device and the position signal delayed by the delay circuit.

8. The optical scanning device according to claim 7,
wherein the determination part is a comparator.

9. The optical scanning device according to claim 2,
wherein the detection device is a position sensitive detector capable of simultaneously detecting the light quantity centroid position and an intensity of light of the incidence light, and
the abnormality detection device detects the abnormal operation based on an intensity signal representing the intensity of light output from the detection device in addition to the position signal.

10. The optical scanning device according to claim 1,
wherein the mirror is swingable around a first axis and a second axis that are orthogonal to each other, and
the detection device detects a two-dimensional position of the incidence light.

11. An abnormality detection method of an optical scanning device including a micromirror device including a mirror that has a reflecting surface for reflecting light and is swingable around at least one axis, and an actuator that allows the mirror to swing, and a control device configured to control an operation of the actuator, the method comprising:
irradiating a back surface of the mirror on a side opposite to the reflecting surface with illumination light; and
detecting an abnormal operation of the mirror based on a temporal fluctuation amount of a position of reflected light of the illumination light that has been reflected by the mirror.
